(19) United States
(12) Patent Application Publication
(10) Pub. No.: US 2024/0145642 A1
(43) Pub. Date: May 2, 2024

(54) MICRO LED DISPLAY WITH RACETRACK STRUCTURE

(71) Applicant: Applied Materials, Inc., Santa Clara, CA (US)

(72) Inventors: Jiacheng FAN, Santa Clara, CA (US); Zhiyong LI, San Jose, CA (US); Da HE, Santa Clara, CA (US)

(21) Appl. No.: 18/495,550

(22) Filed: Oct. 26, 2023

Related U.S. Application Data
(60) Provisional application No. 63/381,399, filed on Oct. 28, 2022.

(51) Int. Cl. H01L 33/50; H01L 25/16

(52) U.S. Cl. CPC H01L 33/505; H01L 25/167; H01L 33/502; H01L 2933/0041

(57) ABSTRACT

Embodiments of the present disclosure generally relate to LED pixels and methods of fabricating LED pixels. The pixel includes a plurality of sub-pixels. Each sub-pixel includes a backplane comprising a top surface, a plurality of sub-pixel isolation structures disposed over the backplane, a micro-LED disposed in the well, a color conversion material disposed over the micro-LED within a well, and a filter layer disposed over the sub-pixel isolation structures and the color conversion material. The sub-pixel isolation structures defining the well. The sub-pixel isolation structures include sidewalls and a top surface. The sidewalls are angled at an angle from the top surface of the backplane to the top surface of the sub-pixel isolation structures.

### CROSS-REFERENCE TO RELATED APPLICATIONS

### Field

This application claims priority to U.S. Provisional Application Ser. No. 63/381,399, filed Oct. 28, 2022, the contents of which are incorporated herein by reference in their entirety.

### BACKGROUND

### Field

Embodiments of the present disclosure generally relate to LED pixels and methods of fabricating LED pixels.

### Description of the Related Art

A light emitting diode (LED) panel uses an array of LEDs, with individual LEDs providing the individually controllable pixel elements. Such an LED panel can be used for a computer, touch panel device, personal digital assistant (PDA), cell phone, television monitor, and the like.

An LED panel that uses micron-scale LEDs based on III-V semiconductor technology (also called micro-LEDs) would have a variety of advantages as compared to OLEDs, e.g., higher energy efficiency, brightness, and lifetime, as well as fewer material layers in the display stack which can simplify manufacturing. However, there are challenges to fabrication of micro-LED panels. For instance, color purity of quantum dot (QD) color conversion materials is not ideal due to the broad band spectrum emission of the LED. In addition, polarizers that are integrated with QDs may reduce the brightness of the red/green/blue (RGB) transmission. These factors may compromise the quality of the display.

Therefore, what is needed in the art is a more efficient QD color conversion layer.

### SUMMARY

In one embodiment, a sub-pixel is disclosed. The sub-pixel includes a backplane comprising a top surface, a plurality of sub-pixel isolation structures disposed over the backplane, a micro-LED disposed in the well, a color conversion material disposed over the micro-LED within the well, and a filter layer disposed over the sub-pixel isolation structures and the color conversion material. Each of the sub-pixel isolation structures defines the well. Each of the sub-pixel isolation structures includes sidewalls and a top surface. The sidewalls form an angle with the top surface of the backplane.

In another embodiment, a pixel is disclosed. The pixel includes a plurality of sub-pixels. Each sub-pixel includes a backplane comprising a top surface, a plurality of sub-pixel isolation structures disposed over the backplane, a micro-LED disposed in the well, a color conversion material disposed over the micro-LED within a well, and a filter layer disposed over the sub-pixel isolation structures and the color conversion material. The sub-pixel isolation structures defining the well. The sub-pixel isolation structures include sidewalls and a top surface. The sidewalls are angled at an angle from the top surface of the backplane to the top surface of the sub-pixel isolation structures.

In yet another embodiment, a method of making a light emitting diode (LED) is disclosed. The method includes patterning a backplane to form sub-pixel isolation structures defining a plurality of wells; disposing a micro-LED in each of the plurality of wells of a plurality of sub-pixels; disposing a first color conversion material in a well of a first sub-pixel; disposing a second color conversion material in a well of a second sub-pixel; disposing a third color conversion material in a well of a third sub-pixel; disposing a filter layer over the sub-pixel isolation structures; and disposing a plurality of micro-lenses over the filter layer and over each of the plurality of wells of the plurality of sub-pixels.

### BRIEF DESCRIPTION OF THE DRAWINGS

So that the manner in which the above recited features of the present disclosure can be understood in detail, a more particular description of the disclosure, briefly summarized above, may be had by reference to embodiments, some of which are illustrated in the appended drawings. It is to be noted, however, that the appended drawings illustrate only exemplary embodiments and are therefore not to be considered limiting of its scope, and may admit to other equally effective embodiments.

FIG. 1A is a schematic, cross-sectional view of a pixel having a racetrack arrangement, according to embodiments.

FIG. 1B is a schematic, cross-sectional view of a sub-pixel having a racetrack arrangement, according to embodiments.

FIG. 1C is a schematic, top view of a sub-pixel having a racetrack arrangement, according to embodiments.

FIG. 2 is a flow diagram of a method of forming a pixel having a racetrack arrangement, according to embodiments.

FIGS. 3A-3G are schematic, cross-sectional views of a backplane during the method of forming a pixel having a racetrack arrangement, according to embodiments.

To facilitate understanding, identical reference numerals have been used, where possible, to designate identical elements that are common to the figures. It is contemplated that elements and features of one embodiment may be beneficially incorporated in other embodiments without further recitation.

### DETAILED DESCRIPTION

Embodiments of the present disclosure generally relate to LED pixels and methods of fabricating LED pixels.

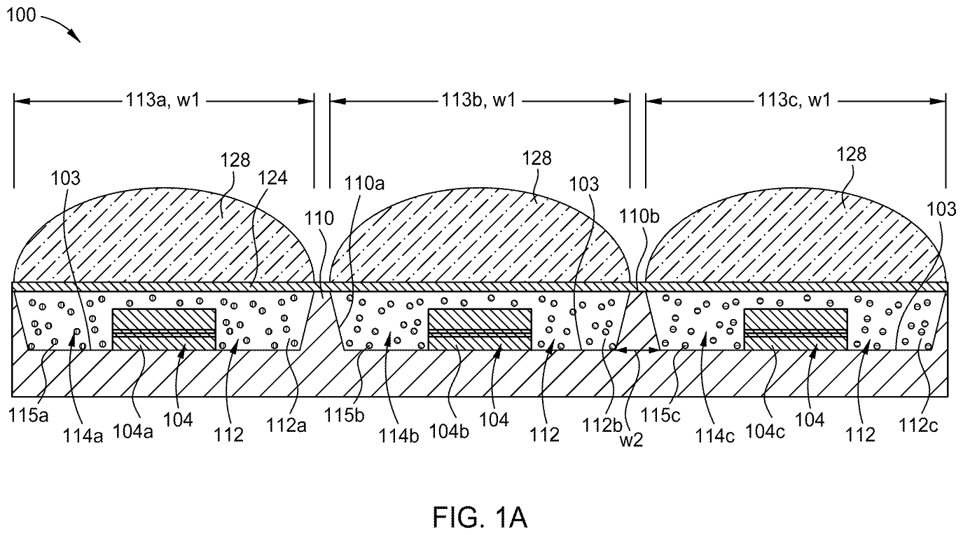

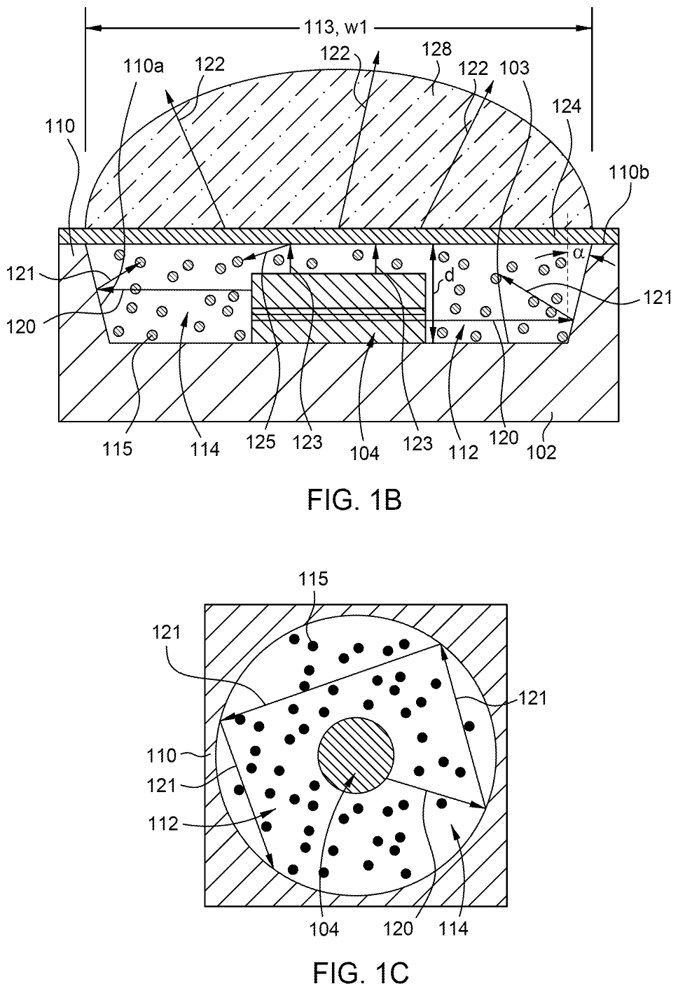

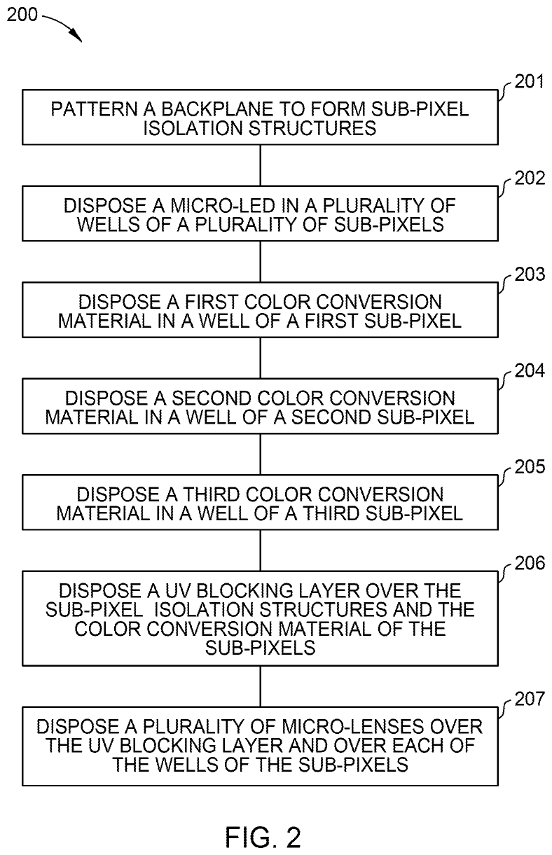

FIG. 1A is a schematic, cross-sectional view of a pixel 100 having a racetrack arrangement. FIG. 1B is a schematic, cross-sectional view of a sub-pixel 112 having the racetrack arrangement. FIG. 1C is a schematic, top view of a sub-pixel 112 having a racetrack arrangement. The pixel 100 includes at least three micro-LEDs 104 disposed on a backplane 102. The micro-LEDs 104 are integrated with backplane circuitry so that each micro-LED 104 can be individually addressed. For example, the circuitry of the backplane 102 can include a TFT active matrix array with a thin-film transistor and a storage capacitor for each micro-LED, column address and row address lines, column and row drivers, to drive the micro-LEDs 104. Alternatively, the micro-LEDs 104 can be driven by a passive matrix in the backplane circuitry. The backplane 102 can be fabricated using conventional CMOS processes. The micro-LEDs 104 may be horizontal emission micro-LEDs 104 or horizontal and vertical emission micro-LEDs 104. The micro-LEDs 104 may emit a light having a wavelength less than about 465 nm, e.g., an ultraviolet (UV) light or other non-visible light.

Adjacent sub-pixel isolation structures 110 define the respective wells 113 of at least three sub-pixels 112. The wells 113 have a depth d of about 1 μm to about 10 μm and a width w1 of about 0.2 μm to about 15 μm. In some embodiments, as shown in FIG. 1C, the well 113 is a circular well. In other embodiments, the well 113 may be a rectangle, a square, an oval, a parallelogram, or other suitable shape. The sub-pixels 112 include a first sub-pixel 112a, a second sub-pixel 112b, and a third sub-pixel 112c. A color conversion material 114 is disposed in the respective wells 113 of the sub-pixels 112. The color conversion material 114 is disposed over a top surface and sidewalls of the micro-LED 104.

The color conversion material 114 may include a plurality of quantum dots 115. In some embodiments, the first sub-pixel 112a is a red sub-pixel with a red color conversion material disposed in a first well 113a, the second sub-pixel 112b is a green sub-pixel with a green color conversion material disposed in a second well 113b, and the third sub-pixel 112c is a blue sub-pixel with a blue color conversion material disposed in a third well 113c. The red color conversion material includes first quantum dots 115a (e.g., red quantum dots), the green color conversion material includes second quantum dots 115b (e.g., green quantum dots), and the blue color conversion material includes third quantum dots 115c (e.g., blue quantum dots).

When a micro-LED 104a of the first sub-pixel 112a is turned on, the red color conversion material will convert the light emitted from micro-LED 104a into red light through interaction of the light with the red quantum dots. When a second micro-LED 104b of the second sub-pixel 112a is turned on, the green color conversion material will convert the light emitted from micro-LED 104b into green light through interaction of the light with the green quantum dots. When a micro-LED 104c of the third sub-pixel 112c is turned on, the blue color conversion material will convert the light emitted from micro-LED 104c into blue light through interaction of the light with the blue quantum dots. In one embodiment, the pixel 100 includes a fourth sub-pixel. The fourth sub-pixel does not include a color conversion material, i.e., color-conversion-layer-free. The fourth sub-pixel may include a sacrificial material. In other embodiments, the at least three sub-pixels 112 include the same color conversion material. The fourth sub-pixel may be later filled with a color conversion material.

The aspect ratio between the depth d and width w1 of the well 113 of the sub-pixels 112 enables more efficient emission of light from the sub-pixel 112. At high aspect ratios, the propagation path of the emitted light from the micro-LEDs 104 is long. Light loss occurs as the emitted light reflects off the sub-pixel isolation structures 110 of the sub-pixel 112, leading to increase quantum dot 115 utilization in high aspect ratio pixels. A decrease in the depth d of the well 113 decreases the aspect ratio between the depth d and the width w1 of the sub-pixel 112. The decrease in the aspect ratio reduces the optical path of the emitted light, enabling decreased and more efficient utilization of the quantum dots 115. The decrease in the aspect ratio further reduces the fabrication burdens of the pixel 100.

The sub-pixel isolation structures 110 include a photoresist material, such as an epoxy-based resist. The photoresist material may be a negative photoresist. The sub-pixel isolation structures 110 have a width w2 of about 1 μm to about 5 μm. The sub-pixel isolation structures 110 include exposed surfaces e.g., sidewalls 110a and a top surface 110b. The sidewalls 110a are angled from the bottom of the sub-pixel isolation structure 110 (e.g., a top surface 103 of the backplane 102) toward the top surface 110b of the sub-pixel isolation structure 110 at an angle α. The angle α is between about 1° and about 89°, such as about 10° and about 80°, such as about 20° and about 70°. The exposed surfaces, i.e., the sidewalls 110a and top surface 110b, of the sub-pixel isolation structures 110 and the top surface 103 of the backplane 102 (e.g., a bottom of the sub-pixel isolation structure 110) may have a reflection material disposed thereon. The reflection material on the exposed sidewalls 110a and top surface 110b provide for reflection of the emitted light to contain the converted light to the respective sub-pixel in order to collimate the light to the display. The reflection material includes, but is not limited to, aluminum, silver, gold, combinations thereof, or the like.

An encapsulation layer may be disposed over the sub-pixel isolation structures 110 and the sub-pixels 112. The pixel 100 includes a UV blocking layer 124 disposed over the sub-pixel isolation structures 110 and the color conversion material 114 of the sub-pixels 112. In embodiments in which there is an encapsulation layer, the UV blocking layer 124 is disposed over the encapsulation layer. In some embodiments, a second passivation layer may be disposed over the UV blocking layer 124.

As light is emitted from the micro-LEDs 104, a horizontally emitted light 120 propagates toward the sidewalls 110a of the well 113 and a vertically emitted light 123 propagates towards the top of the sub-pixel 112. The angle α of the sidewalls 110a enables an increase in the utilization of the horizontally emitted light from the micro-LEDs 104. The horizontally emitted light 120 from the micro-LEDs 104 is reflected off of the sidewalls 110a at the angle α toward the top of the sub-pixel 112 as horizontally reflected light 121. The vertically emitted light 123, the horizontally emitted light 120, and the horizontally reflected light 121 may interact with a quantum dot 115. The vertically emitted light, the horizontally emitted light 120, and the horizontally reflected light 121 that has interacted with a quantum dot 115 is emitted from the well 113 through the UV blocking layer 124 as visible light 122. The circular shape of the well 113 contains the horizontally emitted light 120 and the horizontally reflected light 121 that has not interacted with a quantum dot 115 within the well 113. The UV blocking layer 124 contains the emitted light (e.g., the vertically emitted light 123, the horizontally emitted light 120, and the horizontally reflected light 121) that has not interacted with a quantum dot 115 within the well 113 of the sub-pixel 112 as UV reflected light 125. The reflection material on the top surface 103 of the backplane 102 enables the continued propagation of the emitted light within the well 113 of the sub-pixel 112. The horizontally reflected light 121 and UV reflected light 125 utilize the horizontal distance of the sub-pixel 112 to increase the likelihood of interaction between the horizontally reflected light 121, the UV reflected light 125, and the quantum dots 115, thus enabling an increase in the efficiency of the sub-pixel 112.

A micro-lenses 128 disposed over the UV blocking layer 124 and over each of the wells 113 of the sub-pixels 112. In embodiments including the second passivation layer, the micro-lens 128 is disposed over the second passivation layer. The second passivation layer may include silicon nitride. In some embodiments, the micro-lenses 128 include a resist material, such as a photoresist material, that blocks UV light. The micro-lenses 128 enable the extraction of visible light (e.g., the emitted light colored by the color conversion material 114).

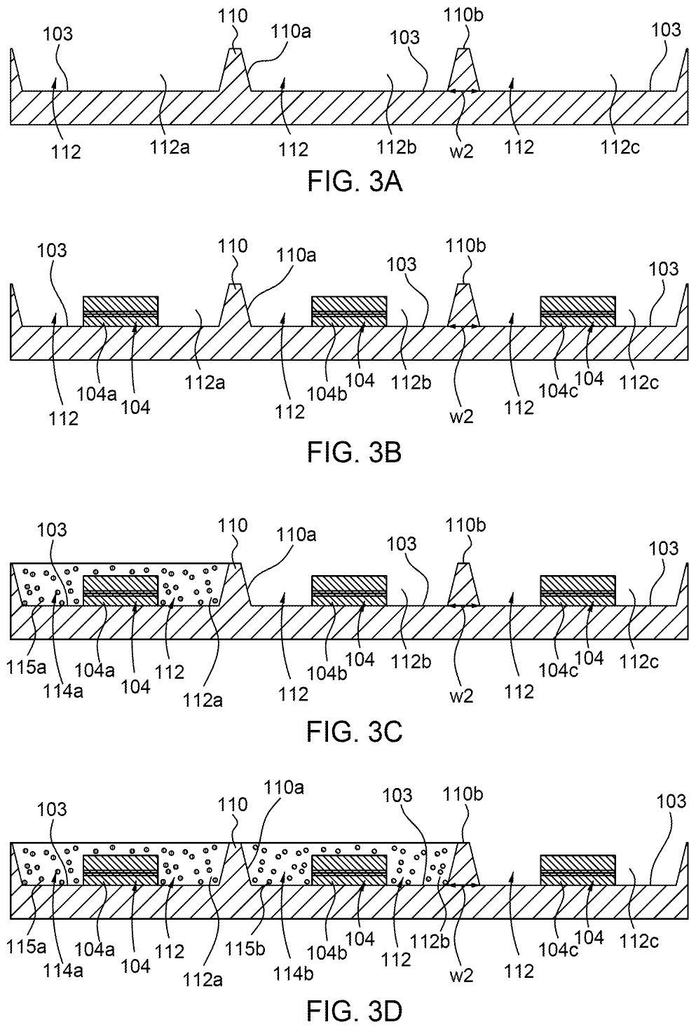

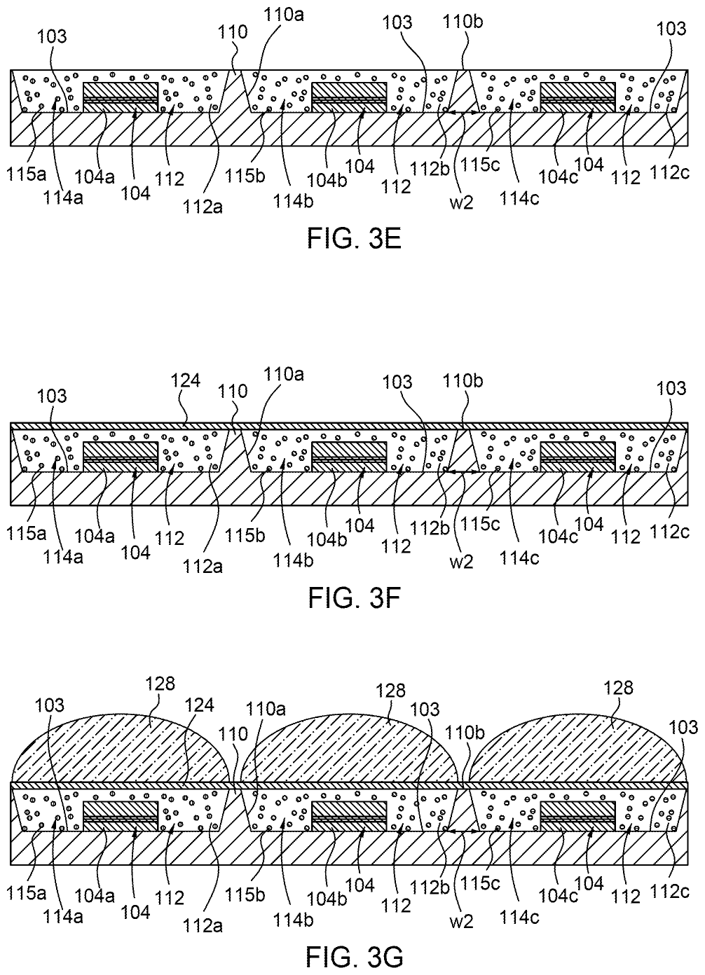

FIG. 2 is a flow diagram of a method 200 of forming a pixel 100 having a racetrack arrangement. FIGS. 3A-3E are schematic, cross-sectional views of the backplane 102 during the method 200. The method 200 begins at operation 201, as shown in FIG. 3A, where a backplane 102 is patterned to form the sub-pixel isolation structures 110. The sub-pixel isolation structures 110 define a plurality of wells 113 of a plurality of sub-pixels 112. In some embodiments, a reflection material is disposed over the exposed portions of the sub-pixel isolation structures 110 (e.g., the sidewalls 110a and the top surface 110b of the sub-pixel isolation structures 110) and a top surface 103 of the backplane 102.

At operation 202, as shown in FIG. 3B, a micro-LED 104 is disposed in the wells 113 of the sub-pixels 112. The micro-LEDs 104 may be horizontal emissions micro-LEDs 104 or horizontal and vertical emission micro-LEDs 104. The micro-LEDs 104 may emit an ultraviolet (UV) light or other non-visible light. The UV light is contained within the well 113 of the sub-pixels 112 using the reflection material disposed over the exposed portions of the sub-pixel isolation structures 110 (e.g., the sidewalls 110a and the top surface 110b of the sub-pixel isolation structures 110) and the top surface 103 of the backplane 102.

At operation 203, as shown in FIG. 3C, a first color conversion material 114a is disposed in a well 113 of a first sub-pixel 112a. The first color conversion material 114a may be disposed using a spin coating process or an inkjet printing process. The first color conversion material 114a includes first quantum dots 115a. The first color conversion material 114a may be a red color conversion material. When a micro-LED 104a of the first sub-pixel 112a is turned on, the red color conversion material will convert the light emitted from micro-LED 104a into red light through interaction of the light with the red quantum dots.

At operation 204, as shown in FIG. 3D, a second color conversion material 114b is disposed in a well 113 of a second sub-pixel 112b. The second color conversion material 114b may be disposed using a spin coating process or an inkjet printing process. The second color conversion material 114b includes second quantum dots 115b. The second color conversion material 114b may be a green color conversion material. When a second micro-LED 104b of the second sub-pixel 112a is turned on, the green color conversion material will convert the light emitted from micro-LED 104b into green light through interaction of the light with the green quantum dots.

At operation 205, as shown in FIG. 3E, a third color conversion material 114c is disposed in a well 113 of a third sub-pixel 112c. The third color conversion material 114c may be disposed using a spin coating process or an inkjet printing process. The third color conversion material 114c includes third quantum dots 115c. The third color conversion material 114c may be a blue color conversion material. When a micro-LED 104c of the third sub-pixel 112c is turned on, the blue color conversion material will convert the light emitted from micro-LED 104c into blue light through interaction of the light with the blue quantum dots.

At operation 206, as shown in FIG. 3F, a filter layer (e.g., a UV blocking layer 124) is disposed over the sub-pixel isolation structures 110 and the sub-pixels 112. The UV light that has been emitted, but which has not interacted with the quantum dots 115 of the color conversion material 114 is contained within the well 113 of the sub-pixel 112 by the UV blocking layer 124.

At operation 207, a plurality of micro-lenses are disposed over the UV blocking layer 124 and over each of the wells 113 of the sub-pixels 112. The micro-lenses 128 enable the extraction of visible light (e.g., the emitted light colored by the color conversion material 114). The UV blocking layer contains the UV light emitted from the micro-LEDs 104, which has not interacted with the quantum dots 115, within the well 113.

In summary, a pixel having a racetrack arrangement is disclosed. The pixel has a plurality of sub-pixels defined by sub-pixel isolation structures. The sub-pixel isolation structures further define wells of the sub-pixels. The wells have a circular shape. A reflection material is disposed over the sub-pixel structures and the top surface of the backplane. A micro-LED is disposed in the wells. A color conversion material is disposed in the wells over the micro-LED. The depth of the wells and the width of the wells have an aspect ratio that enables more efficient utilization of quantum dots in the color conversion material through interactions with the light emitted from the micro-LEDs. The reflection material contains the emitted light that has not interacted with the color conversion layer within the sub-pixel, increasing the likelihood of interactions between the emitted light and the color conversion layer.

While the foregoing is directed to embodiments of the present disclosure, other and further embodiments of the disclosure may be devised without departing from the basic scope thereof, and the scope thereof is determined by the claims that follow.

What is claimed is:

1. A sub-pixel, comprising:
a backplane comprising a top surface;
a plurality of sub-pixel isolation structures disposed over the backplane, each of the sub-pixel isolation structures defining a well, each of the sub-pixel isolation structures comprising:
sidewalls; and
a top surface, wherein the sidewalls form an angle with the top surface of the backplane;
a micro-LED disposed in the well;
a color conversion material disposed over a top surface and sidewalls of the micro-LED within the well; and
a filter layer disposed over the sub-pixel isolation structures and the color conversion material.

2. The sub-pixel of claim 1, wherein a reflection material disposed over the sidewalls of the sub-pixel isolation structures, the top surface of the sub-pixel isolation structures, and the top surface of the backplane.

3. The sub-pixel of claim 1, wherein the angle between the sidewalls and the top surface of the backplane is from about 1° and about 89°.

4. The sub-pixel of claim 1, wherein a micro-lens disposed over the filter layer.

5. The sub-pixel of claim 1, wherein a light emitted from the micro-LED is less than about 465 nm.

6. The sub-pixel of claim 1, wherein the color conversion material comprises a plurality of quantum dots configured to convert a light emitted from the micro-LED into a visible light.

7. The sub-pixel of claim 1, wherein a depth of the well is about 1 μm to about 10 μm.

8. The sub-pixel of claim 1, wherein a width of the well is about 0.2 μm to about 15 μm.

9. A pixel, comprising:
a plurality of sub-pixels, each sub-pixel comprising:
a backplane comprising a top surface;
a plurality of sub-pixel isolation structures disposed over the backplane, the sub-pixel isolation structures defining a well, the sub-pixel isolation structures comprising:
sidewalls; and
a top surface, wherein the sidewalls are angled at an angle from the top surface of the backplane to the top surface of the sub-pixel isolation structures;
a micro-LED disposed in the well;
a color conversion material disposed over a top surface and sidewalls of the micro-LED within the well; and
a filter layer disposed over the sub-pixel isolation structures and the color conversion material.

10. The sub-pixel of claim 9, wherein a reflection material disposed over the sidewalls of the sub-pixel isolation structures, the top surface of the sub-pixel isolation structures, and the top surface of the backplane.

11. The sub-pixel of claim 9, wherein the angle of the sidewall is from about 1° and about 89°.

12. The sub-pixel of claim 9, wherein a micro-lens disposed over the filter layer.

13. The sub-pixel of claim 9, wherein a light emitted from the micro-LED is less than about 465 nm.

14. The sub-pixel of claim 9, wherein the color conversion material comprises a plurality of quantum dots configured to convert the light emitted from the micro-LED into visible light.

15. The sub-pixel of claim 9, wherein a depth of the well is about 1 μm to about 10 μm.

16. The sub-pixel of claim 9, wherein a width of the well is about 0.2 μm to about 15 μm.

17. The pixel of claim 9, wherein the plurality of sub-pixels comprise:
a first sub-pixel, wherein the color conversion material of the first sub-pixel comprises a first color conversion material;
a second sub-pixel, wherein the color conversion material of the second sub-pixel comprises a second color conversion; and
a third sub-pixel, wherein the color conversion material of the third sub-pixel comprises a third color conversion material.

18. The pixel of claim 17, wherein:
the first color conversion material is a red color conversion material;
the second color conversion material is a green color conversion material; and
the third color conversion material is a blue color conversion material.

19. A method of forming a sub-pixel, comprising:
patterning a backplane to form sub-pixel isolation structures defining a plurality of wells;
disposing a micro-LED in each of the plurality of wells of a plurality of sub-pixels;
disposing a first color conversion material in a well of a first sub-pixel;
disposing a second color conversion material in a well of a second sub-pixel;
disposing a third color conversion material in a well of a third sub-pixel;
disposing a filter layer over the sub-pixel isolation structures; and
disposing a plurality of micro-lenses over the filter layer and over each of the plurality of wells of the plurality of sub-pixels.

20. The method of claim 19, wherein the first color conversion material, the second color conversion material, and the third color conversion material are formed using a spin coating process or an inkjet deposition process.
